(19) United States
(12) Patent Application Publication
(10) Pub. No.: US 2014/0168629 A1
(43) Pub. Date: Jun. 19, 2014

(54) DRAWING APPARATUS, AND ARTICLE MANUFACTURING METHOD

(71) Applicant: CANON KABUSHIKI KAISHA, Tokyo (JP)

(72) Inventors: Toshihiko NISHIDA, Utsunomiya-shi (JP); Hideki INA, Tokyo (JP)

(73) Assignee: CANON KABUSHIKI KAISHA, Tokyo (JP)

(21) Appl. No.: 14/132,240

(22) Filed: Dec. 18, 2013

(30) Foreign Application Priority Data
Dec. 19, 2012 (JP) 2012-277472

(51) Int. Cl. H01J 37/30

(52) U.S. Cl. CPC H01J 37/3002
USPC 355/77; 250/492.22

(57) ABSTRACT

Provided is a drawing apparatus including a plurality of drawing devices each of which is configured to draw a pattern on a substrate with a plurality of charged particle beams, the plurality of drawing devices performing respective drawings in parallel, the drawing apparatus comprising: a measuring device configured to measure a flatness of the substrate, wherein each of the plurality of drawing devices comprises: a charged particle optical system configured to irradiate the substrate with the plurality of charged particle beams; and a controller configured to control an operation of the charged particle optical system so as to compensate for distortion of the pattern which is determined by data of inclination of a charged particle beam of the charged particle beams with respect to an axis of the charged particle optical system and data of the flatness measured by the measuring device.

### BACKGROUND OF THE INVENTION

1. Field of the Invention

The present invention relates to a drawing apparatus including a plurality of drawing devices, and an article manufacturing method using the same.

2. Description of the Related Art

Drawing apparatuses that, perform drawing on a substrate by controlling deflection scanning and blanking of a plurality of charged particle beams (e.g., electron beams) are known. For example, assume that the drawing apparatus for use in manufacturing a semiconductor device draws the device pattern of the (n+1)th layer (where n is a natural number) on the device pattern of the nth layer in a semiconductor process. In this case, alignment measurement for performing drawing by overlaying the pattern of the (n+1)th layer on the pattern of the nth layer formed on the substrate is performed prior to drawing. In the alignment measurement, the positions of a plurality of alignment marks formed on the wafer are measured with an off-axis alignment scope (OAS) or the like, and the positions of the shots formed on the wafer are determined on the basis of the measured values. The drawing apparatus moves the substrate in accordance with the positions of the shots determined as described above and then overlays the pattern of the (n+1)th. layer on the pattern of the nth layer on each of the shots to thereby perform drawing.

Here, a shift amount or a shift extent from the vertical direction (a direction vertical to a substrate surface) of the incident direction of a charged particle beam to a wafer surface is referred to as “telecentric characteristics” or “the degree of telecentricity” using the term “telecentricity” or “telecen” as an abbreviation. Japanese Patent Laid-Open No. 2005-109235 points out that a low degree of telecentricity causes distortion in the drawn pattern and discloses a drawing system that measures the shift amount and corrects the distortion. In addition, Japanese Patent Laid-Open No. 2012-4461 discloses a drawing apparatus that measures the position of a reference mark formed on a wafer stage with a charged particle beam having excellent telecentric characteristics in order to perform baseline measurement with high accuracy.

For example, the flatness (planarity) of a wafer is about 1 μm. When drawing is performed on such a wafer, the product, of a defocus amount. (1 μm) to such an extent and the degree of telecentricity (e.g., 1 mRad) is 1 nm, so the charged particle beam may laterally shift by about 1 nm on the wafer. In order to satisfy micronization demands for recent semiconductor devices, the lateral shift of about 1 nm is still non-negligible. However, the drawing apparatus disclosed in Japanese Patent Laid-Open No. 2005-109235 or Japanese Patent Laid-Open No. 2012-4461 takes into account telecentric characteristics but does not take into account the flatness of the wafer. Furthermore, in the drawing apparatus, the number of wafers to be treated (throughput) per unit time is an important performance.

### SUMMARY OF THE INVENTION

The present invention provides, for example, a drawing apparatus advantageous in terms of overlay precision and throughput.

According to an aspect of the present invention, a drawing apparatus including a plurality of drawing devices each of which is configured to draw a pattern on a substrate with a plurality of charged particle beams, the plurality of drawing devices performing respective drawings in parallel, the drawing apparatus comprising: a measuring device configured to measure a flatness of the substrate, wherein each of the plurality of drawing devices comprises: a charged particle optical system configured to irradiate the substrate with the plurality of charged particle beams; and a controller configured to control an operation of the charged particle optical system so as to compensate for distortion of the pattern which is determined by data of inclination of a charged particle beam of the charged particle beams with respect to an axis of the charged particle optical system and data of the flatness measured by the measuring device.

Further features of the present invention will become apparent from the following description of exemplary embodiments with reference to the attached drawings.

### BRIEF DESCRIPTION OF THE DRAWINGS

FIG. 1 is a diagram illustrating a configuration of a drawing apparatus according to one embodiment of the present invention.

FIG. 2A is a diagram illustrating electron beam reference position measurement.

FIG. 2B is a diagram illustrating electron beam reference position measurement.

FIG. 3 is a diagram illustrating a drawing layout for explaining basic drawing processing.

FIG. 4 is a flowchart illustrating the flow of basic drawing processing.

FIG. 5 is a diagram illustrating an exemplary map of the telecentricity of each electron beam.

FIG. 6 is a diagram illustrating the flatness of a wafer.

FIG. 7 is a diagram illustrating a positional shift amount generated on the wafer surface.

FIG. 8 is a diagram illustrating an exemplary relationship between the degree of telecentricity of an electron beam and the wafer flatness.

FIG. 9 is a flowchart illustrating the flow of correcting drawing data.

FIG. 10 is a diagram illustrating blanker data in one electron beam.

FIG. 11 is a diagram illustrating the relationship between data on a beam grid and a data grid.

FIG. 12 is a diagram illustrating an example of the result of correction of drawing data on a beam grid.

FIG. 13A is a flowchart illustrating the flow of processing for one wafer in a drawing system.

FIG. 13B is a time chart illustrating the flow of processing corresponding to that shown in FIG. 13A.

FIG. 14 is a block diagram illustrating a configuration of a drawing system according to one embodiment of the present invention.

FIG. 15 is a time chart of the drawing system.

FIG. 16 is a time chart of the drawing system explicitly illustrating processing performed in a load lock chamber.

FIG. 17 is a graph illustrating the amount of production per unit time when the steady state is sufficiently long.

FIG. 18 is a graph illustrating the amount of production per unit time when the number of units is large.

### DESCRIPTION OF THE EMBODIMENTS

Hereinafter, preferred embodiments of the present invention will be described with reference to the drawings.

Firstly, a description will foe given of a

drawing apparatus (drawing system) according to a first embodiment of the present invention. The drawing apparatus of the present embodiment is a cluster system including a plurality of multi-beam type drawing devices each of which draws a predetermined pattern at a predetermined position on a substrate by deflecting a plurality of charged particle beams and by independently controlling the blanking (OFF irradiation) of the charged particle beams. Here, a charged particle beam may be, for example, an electron beam or an ion beam. In the present embodiment, a description will be given by faking an example of an electron beam as a charged particle beam. Also, a substrate serving as an object to be treated is, for example, a wafer consisting of single crystal silicon. A photosensitive resist is coated on the surface of the substrate. In advance of the description of the drawing apparatus, a description will be firstly given of the configuration of one drawing device 100 as a drawing device which may be employed in the drawing apparatus of the present embodiment.

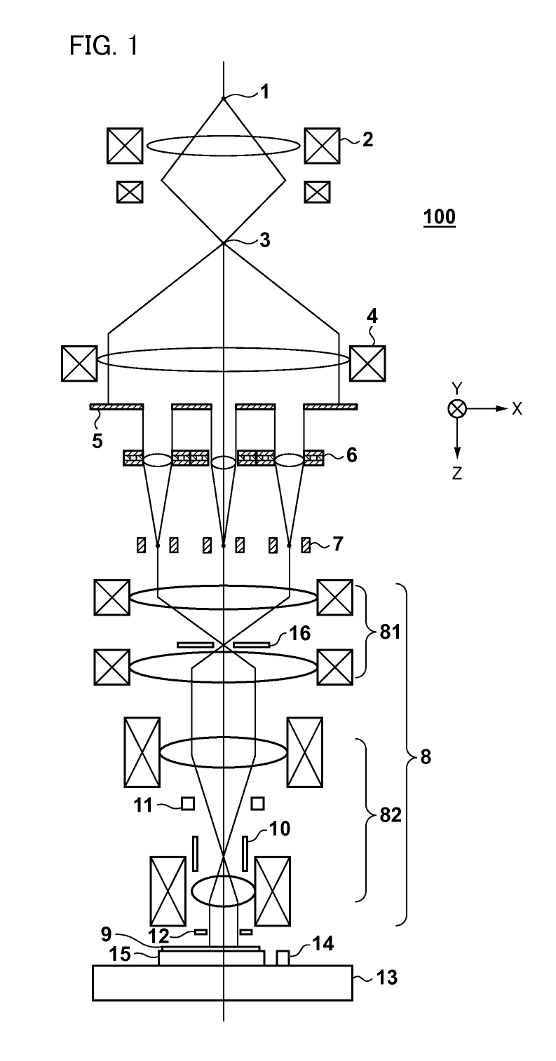

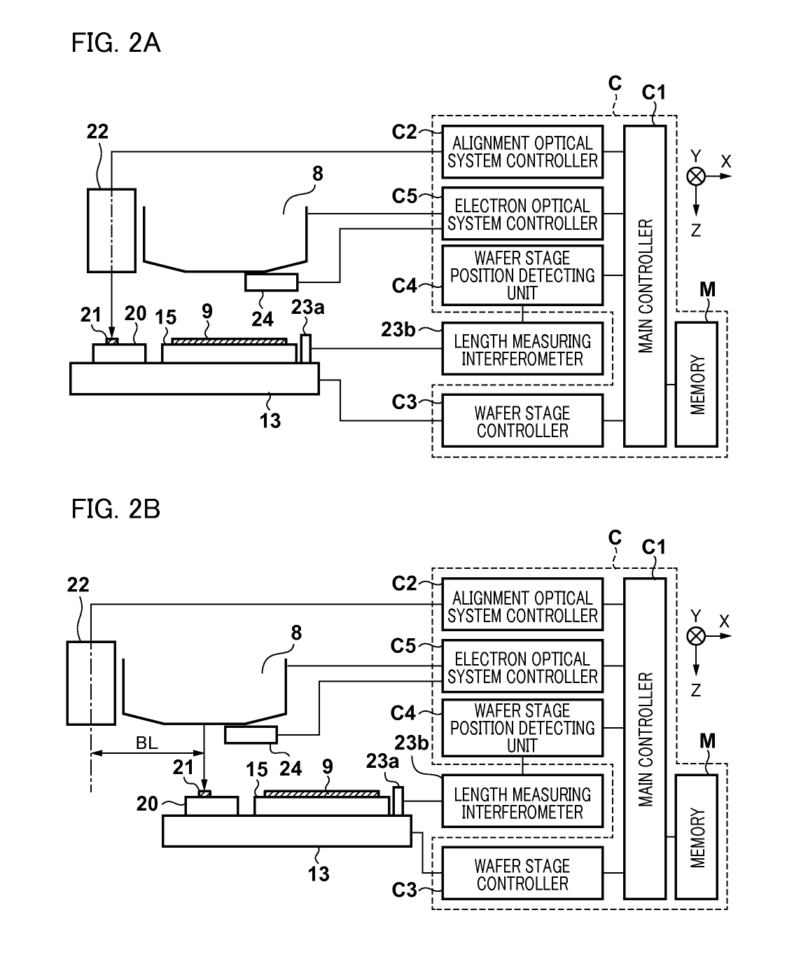

FIG. 1 is a schematic diagram illustrating a configuration of a drawing device 100 which may be employed in the drawing apparatus of the present embodiment. In FIG. 1, a description will be given in which the Z axis is in an nominal irradiation direction of an electron beam to a wafer 9, and the X axis and the Y axis are mutually oriented in directions orthogonal to a plane perpendicular to the Z axis. An electron beam emitted from an electron source 1 forms an image 3 of the electron source 1 via an optical system 2 which shapes the beam. The electron beam from the image 3 is converted into a nearly collimated electron beam by a collimator lens 4. The nearly collimated electron beam passes through an aperture array 5. The aperture array 5 includes a plurality of apertures and splits an electron beam into a plurality of electron beams. The plurality of electron beams split by the aperture array 5 forms intermediate images of the image 3 by an electrostatic lens array 6 in which a plurality of electrostatic lenses is formed. A blanker array 7 in which a plurality of blankers are formed as electrostatic deflectors is located on the intermediate image plane. An electron optical system (charged particle optical system) 8 constituted by two-step symmetric magnetic doublet lenses 81 and 82 is located downstream of the intermediate image plane, and a plurality of intermediate images are projected onto the wafer 9. The electron optical system 8 has an axis in the Z-direction and constitutes an electron optical system that emits and images a plurality of electron beams onto the surface of the wafer 9. An electron beam deflected by the blanker array 7 is blocked by a blanking aperture 16, and thus, does not irradiate the wafer 9. On the other hand, an electron beam which is not deflected by the blanker array 7 is not blocked by the blanking aperture 16, and thus, irradiates the wafer 9. The lower doublet lens 82 accommodates a deflector 10 that simultaneously displaces a plurality of electron beams to a desired position in the X- and Y-directions and a focusing coil 12 that simultaneously adjusts the focuses of the plurality of electron beams. A wafer stage (stage) 13 holds the wafer 9 and is movable in the X- and Y-directions. A wafer chuck (electrostatic chuck) 15 for sucking the wafer 9 is placed on the wafer stage 13. The shape of each electron beam at. a position defined on the irradiation surface of the wafer 9 is measured by a defector 14 including knife edges. Furthermore, a stigmator 11 adjusts the astigmatism of the electron optical system 8. Note that the plurality of elements above constituting the drawing device 100 is integrally controlled by a controller (second controller) C (see FIGS. 2A and 2B).

The drawing device 100 draws a pattern in a plurality of shots (drawing areas) on the wafer 9 by appropriately deflecting the electron beams while moving the wafer stage 13 by a step-and-repeat operation or a scanning operation. In drawing the pattern, the drawing device 100 needs to measure an electron beam reference position relative to the wafer stage 13. An electron beam reference position is measured with an off-axis alignment scope and electron beams in the following way.

FIGS. 2A and 2B are enlarged views of the portion surrounding the wafer 9 in the drawing device 100 shown in FIG. 1 in order to explain electron beam reference position measurement. Firstly, in FIG. 2A, a reference mark table 20 is placed on the wafer stage 13, and a reference mark 21 is formed on the reference mark table 20. An image of the reference mark 21 is detected by an off-axis alignment scope 22, and an image signal is processed by an alignment, optical system controller C2 to thereby specify the position of the reference mark 21 relative to the optical axis of the alignment scope 22. At this time, a wafer stage position detecting unit C4 measures a position P1 of the wafer stage 13 with a length measuring interferometer 23b including a mirror 23a placed on the wafer stage 13 and then stores information about the position P1 in a memory M via a main controller C1. The alignment scope 22 irradiates the reference mark 21 with light and detects the reflected light of irradiated light to thereby measure the position of the reference mark 21. The length measuring interferometer 23b serves as one detector which detects the position of the wafer stage 13 in the X- and Y-directions perpendicular to the Z-direction of the wafer stage 13 and the axis of the electron optical system 8. Next, as shown in FIG. 2B, a wafer stage controller C3 moves the position of the reference mark 21 to the electron beam drawing position, and the main controller C1 uses the electron beam to detect a position P2 of the reference mark 21. In the present embodiment, an electron optical system controller C5 causes an electron beam detector 24 to detect secondary electrons reflected from the reference mark 21 while scanning the wafer stage 13 so that the position P2 is specified. Based on the difference between the positions (coordinate positions) of the wafer stage 13 when the positions P1 and P2 are detected, a baseline BL, that is, the difference between the position on the wafer 9, at which measurement is performed by the alignment optical system, and the position on the wafer 9, at which measurement is performed with the electron beam, is measured,

Next, a description will be given of basic

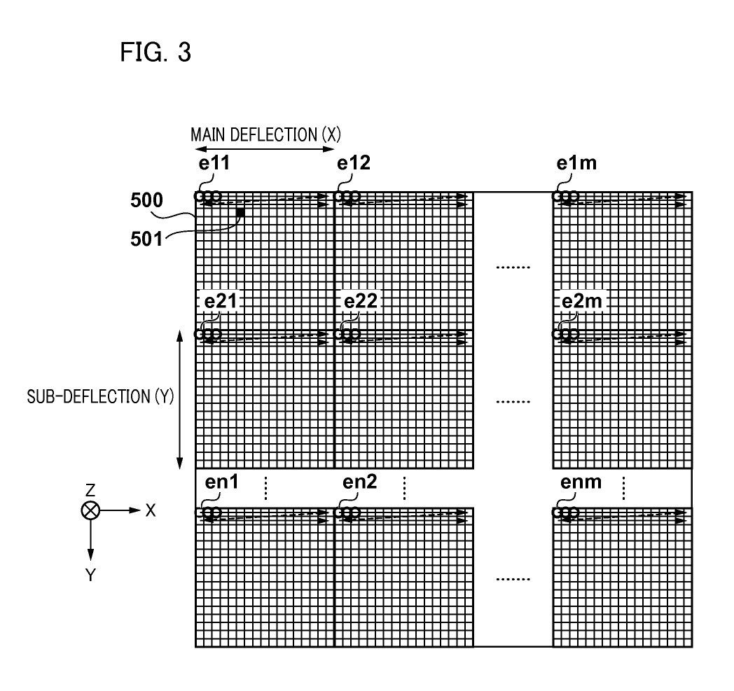

drawing processing performed by the drawing device 100. FIG. 3 is a schematic diagram illustrating a drawing layout for explaining the basic drawing method. In the example shown in FIG. 3, it is assumed that the X-direction is defined as a main deflection, and the Y-direction is defined as a sub-deflection. It is also assumed that m electron beams are juxtaposed in the X-direction, and n electron beams are juxtaposed in the Y-direction. Firstly, the X- and Y-direction deflectors 10 and the wafer stage 13 are controlled such that an upper left drawing grid 501 in a drawing area 500 of each electron beam is irradiated with the electron beam. Here, upon driving of the blanker array 7, the drawing grid 501 is irradiated with the electron beam for a predetermined time specified for each drawing grid 501 based on drawing data to thereby perform drawing. As the electron beam is sequentially moved in the main deflection (X) right direction by the X-direction deflector, each drawing grid is sequentially drawn. After drawing on one row is completed, the X-direction deflector returns to the left end, and drawing starts on the next row. At this time, the wafer stage 13 moves at a constant speed in the sub-deflection (Y) upper direction. The Y-direction deflector adjusts the amount of deflection while following the movement of the wafer stage 13. After drawing on one row is completed, the Y-direction deflector returns to the initial position for drawing on the next row. Thus, the Y-direction deflector can deflect the electron beam at a grid width corresponding to one row. By repeating this operation, drawing can be performed over the drawing area 500 of each electron beam.

In drawing device 100, the environment must foe evacuated in order to avoid attenuation of the electron beam for drawing. Hence, when the flatness of the wafer is measured within the drawing device 100, the wafer flatness needs to be measured in a vacuum as well. As a method for measuring the flatness, a method which uses, for example, light triangulation (oblique incidence+image shift-scheme) or a capacitance sensor is available. This measurement method is not particularly limited to specific examples in the present invention as long as it can be performed in a vacuum. While a description will be given below again, in the drawing apparatus 200, flatness measurement is performed by an independent metrology station 205 instead of a drawing station 206 corresponding to the drawing device 100.

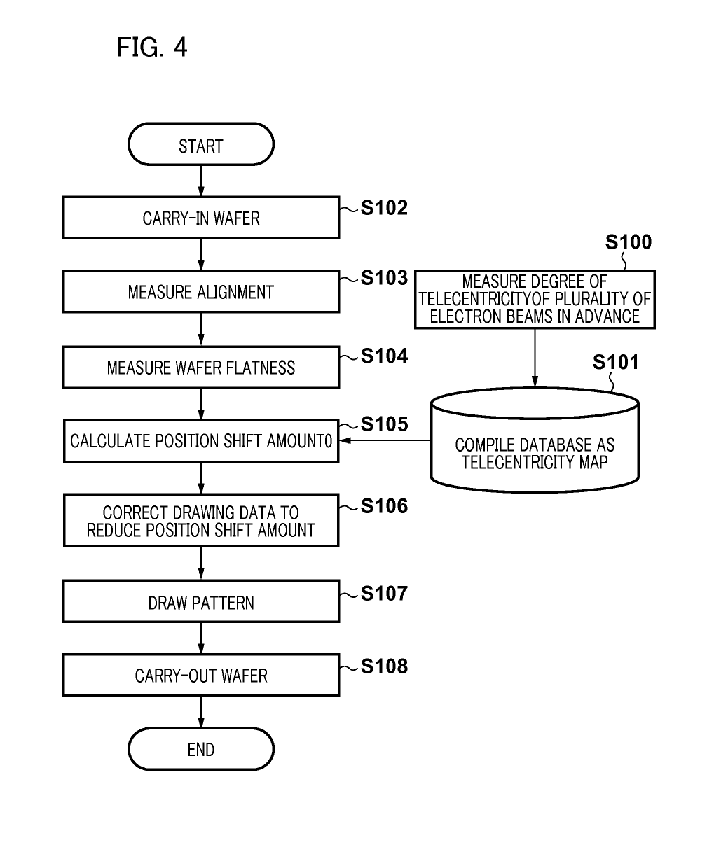

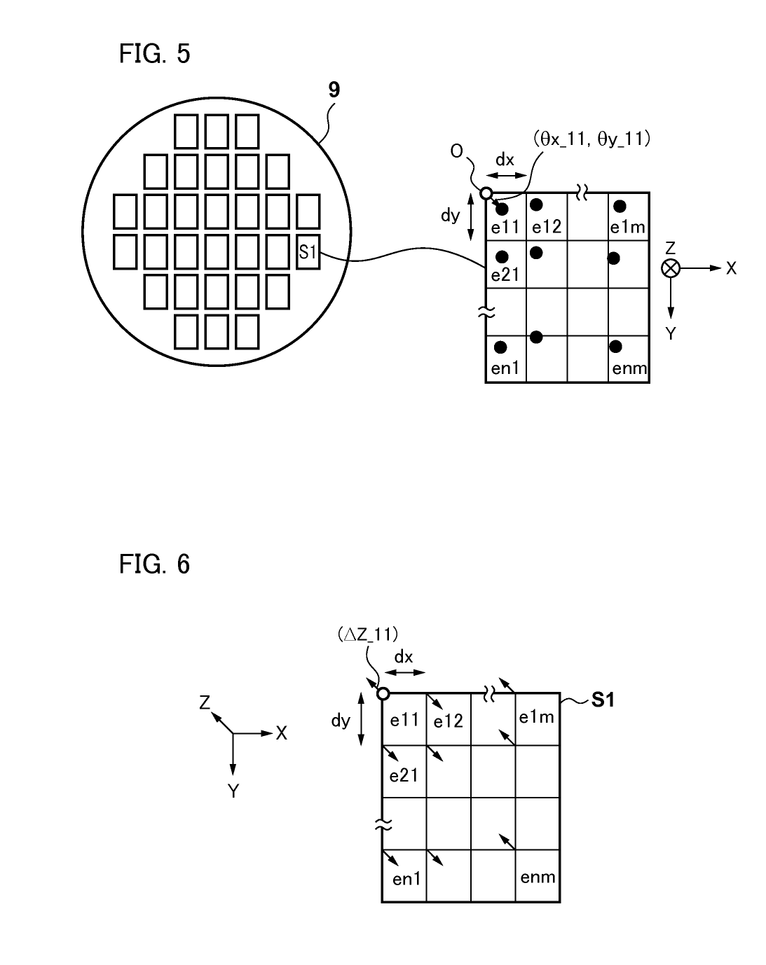

FIG. 4 is a flowchart illustrating the flow of basic drawing processing. Firstly, the main controller C1 measures the degree of telecentricity of a plurality of electron beams (step S100) in advance before carrying out a series of drawing processing steps from carrying-in to carrying-out of the wafer 9. Then, the main controller C1 compiles database of the degree of telecentricity (shift amount from perpendicularity: inclination) measured in step S100 as a map of the telecentricity (step S101). FIG. 5 is a schematic diagram illustrating an exemplary map of the telecentricity of each of a plurality of electron, beams in the shot S1 on the wafer 9. In FIG. 5, a map of the telecentricity of each of a total of m electron beams in the X-direction and n electron beams in the Y-direction is shown. For example, the degree of telecentricity of an electron beam eij (i=1 to n, j=1 to m; the same applies hereafter) is represented by (θx_ij, θy_ij). Furthermore, the interval between adjacent, electron beams in the X-direction is defined as Lx which is the same as that of the width of the main deflection (X) direction shown in FIG. 3 and the interval between adjacent electron beams in the Y-direction is defined as Ly which is the same as that, of the width of the sub-deflection (Y) direction.

Next, as a series of drawing processing steps, the main controller C1 loads the wafer 9 on the wafer stage 13 (the wafer chuck 15), and performs pre-focusing to allow alignment measurement (step S102). Next, the main controller C1 causes the alignment scope 22 to perform alignment measurement (e.g., global alignment measurement) for the wafer 9 (step S103).

Next, the main controller C1 performs flatness measurement for the entire surface of the wafer 9 to be drawn (step S104). A measurement device or a measurement method which may be employed for measurement is not particularly limited. Any measurement device or any measurement method may be used as long as a required measurement precision is obtained. FIG. 6 is a schematic diagram illustrating the flatness of the wafer 9. In FIG. 6, the direction of a vector indicates the direction of flatness, and the magnitude of the vector indicates the degree of flatness far the sake of convenience. The flatness is obtained at pitches equivalent to the intervals Lx and Ly (not shown) between adjacent electron beams and the flatness corresponding to the electron beam eij is ΔZ_ij. Although the flatness control resolution is equivalent to the intervals between adjacent electron beams, there is no need to measure the flatness at pitches equivalent to the intervals between adjacent electron beams. The flatness may be measured at pitches larger than the intervals between adjacent electron beams, and the flatness control resolution interpolated by these beam intervals may be used.

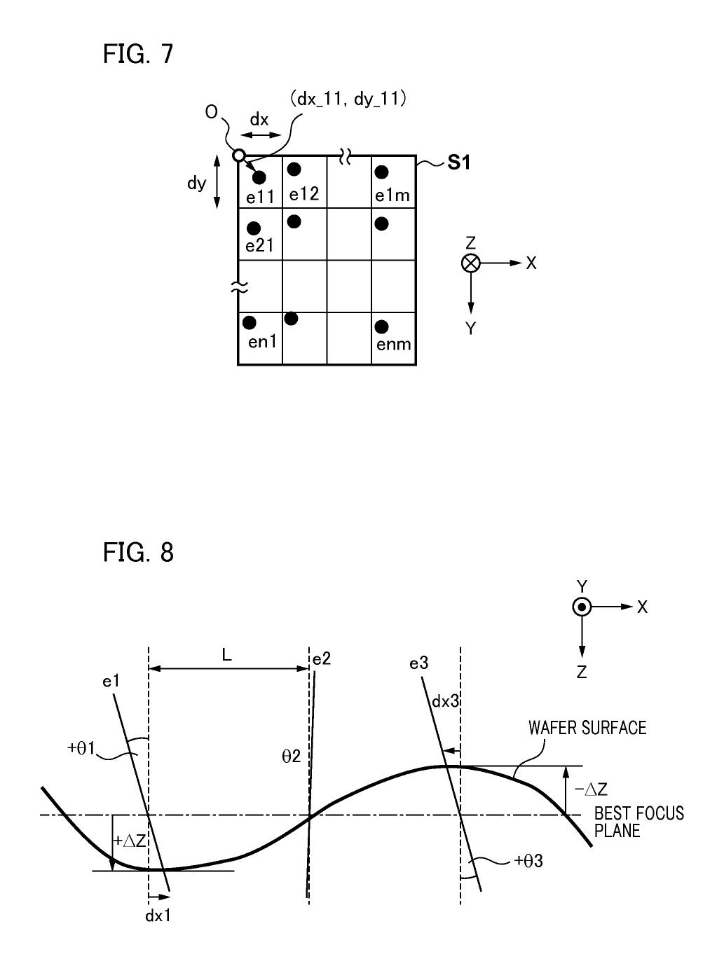

Next, the main controller C1 calculates the positional shift amount of each electron beam on the surface of the wafer 9 based on the telecentricity map acquired and stored in step S101 and information about the flatness of the wafer 9 obtained in step S104 (step S105). FIG. 7 is a schematic diagram illustrating a positional shift amount generated on the surface of the wafer 9, which is obtained from the product of the degree of telecentricity of each electron beam and the flatness. For example, the positional shift amount of the electron beam eij is represented by (dx_ij, dy_ij). Hereinafter, a description will be given of a method for specifically determining the positional shift amount.

FIG. 8 is a schematic diagram illustrating the relationship between the degree of telecentricity of three electron beams and the wafer flatness. While a description will be qiven of the positional shift in the X-direction alone, the same also applies to the positional shift in the Y-direction. Let ei be each electron beam, L (Lx) be the interval between adjacent electron beams, θi be the degree of telecentricity of this electron beam ei (the counterclockwise direction is defined as the positive direction), ΔZ be the flatness of the wafer (the downward direction on the paper surface is defined as the positive direction), and dxi be the positional shift amount. Furthermore, assume that the positional shift of each electron beam on a best focus plane has already been corrected. As a method for determining a best focus plane, various methods are available, including a method for obtaining a best focus plane by least-squares approximation for the data on the wafer surface so as to minimize the RMS value, and a method for determining a plane which minimizes the maximum value of the difference from each data on the wafer surface so as to eliminate any point with too much defocusing. As described above, any method for determining a best focus plane may be employed and is not particularly limited.

For example, the electron beam e1 has the degree of telecentricity −θ1, and drawing is performed at a position +ΔZ from the best focus plane of the wafer 9. In this case, the positional shift amount dx1 on the wafer 9 is determined by the following Formula (1):

dx1=θ1×Δz (1)

Likewise, the electron beam e3 has the degree of telecentricity +θ3, and drawing is performed at a position −ΔZ from the best focus plane of the wafer 9. In. this case, the positional shift amount dx3 on the wafer 9 is determined by the following Formula (2):

dx3=θ3×Δz (2)

Note that the electron beam e2 has a low degree of telecentricity θ2, and the wafer flatness is also nearly corresponding to the best focus plane, so that the positional shift amount dx2 on the wafer 9 is small.

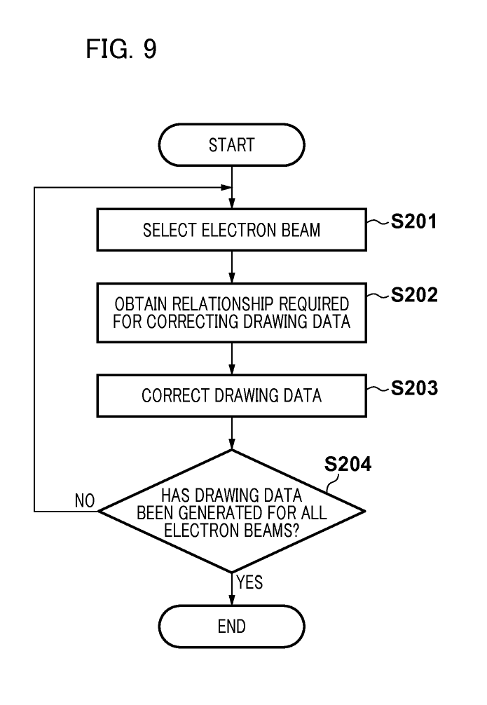

Next, the main controller C1 corrects (regenerates) drawing data generated in advance so as to reduce the positional shift, amount, on. the wafer 9 obtained in step S105 (step S106). FIG. 9 is a flowchart illustrating the flow of correction of drawing data in step S106. Here, when one deflector collectively controls a plurality of electron beams (the electron beams e11 to enm), deflection of the plurality of electron beam cannot be controlled individually. Thus, a drawing error needs to be reduced by correcting drawing data for each individual electron beam. Firstly, the main controller C1 selects one of a plurality of electron beams (step S201).

Next, the main controller C1 obtains the relationship required for correcting drawing data (step S202). In the present embodiment, it is assumed that the shift amount, and the rotation error and magnification error upon deflection are uniquely determined especially in the X- and Y-direction deflection ranges Lx and Ly of the same electron beam.

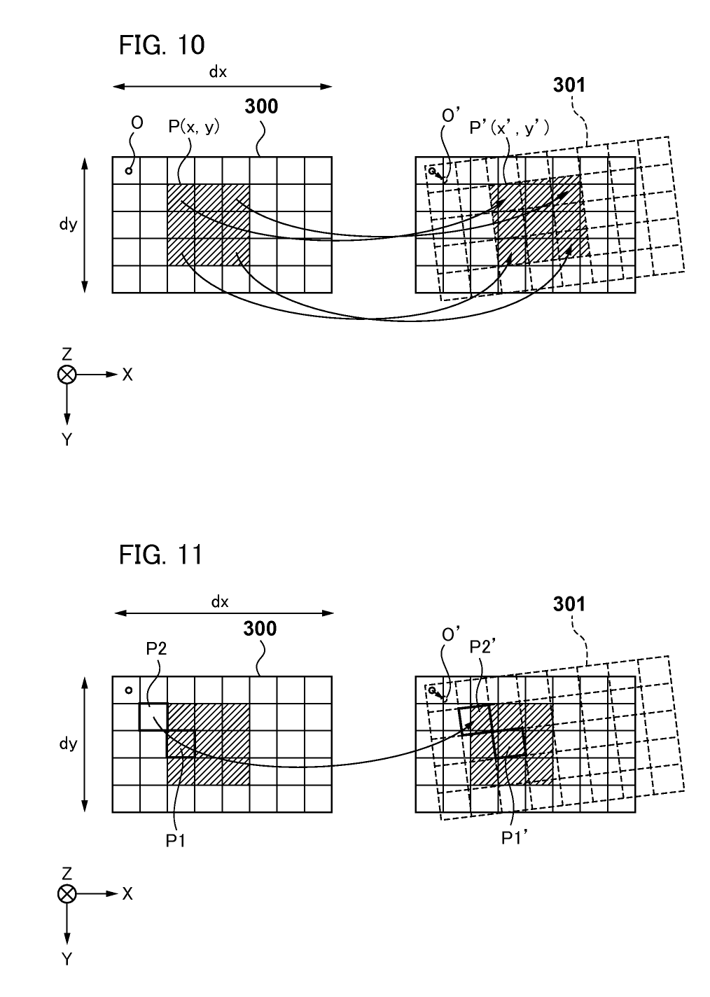

FIG. 10 is a schematic diagram illustrating blanker data in one selected electron beam (for example, the electron beam e11), i.e., a data grid 300, and a beam grid 301 when drawing is actually performed on the wafer 9. In particular, the arrow shown in FIG. 10 shows an example in which data on the data grid 300 is drawn on the beam grid 301 upon deflecting the electron beam e11. An origin O when the electron beam e11 is not deflected is drawn at a point O′. The amount of shift from the origin O to the point O′ corresponds to the aforementioned positional shift amount (dx_11, dy_11) which is obtained from the product of the degree of telecentricity of the electron beam and the wafer flatness. Although the origin O is shown on the upper left corner in the deflection ranges Lx and Ly, the origin O may also be set at the center of the deflection range Lx. As shown in FIG. 10, when the present embodiment is not applied, given data P on the data grid 300 is drawn at data P′ on the beam grid 301, so that a desired pattern (a 3×3 hole pattern in this case) cannot be drawn.

The coordinates P′(x′, y′) of the data P′ on the beam grid 301 on the wafer 9 is represented by the following Formula (3):

$$( \begin{matrix}{x}^{′} \\ {y}^{′}\end{matrix} ) = ( \begin{matrix}dx \\ dy\end{matrix} ) = ( \begin{matrix}mx cos θ x & - m x sin θ y \\ mx sin θ x & my cos θ y\end{matrix} ) ( \begin{matrix}x \\ y\end{matrix} ) \qquad ( 3 )$$

Where dx and dy denote the shift components (translation components) of the electron beam, mx and my denote the magnification components of the electron beam upon deflection, and θx and θy denote the rotation components of the electron beam upon deflection. In general, x′ and y′ are expressed as linear expression for x and y as shown in the following Formula (4). Note that Formulae (4) are not limited to linear expression for x′ and y′, and can also be expressed as polynomials for x and y as required.

$$\{ \begin{matrix}{x}^{′} = {a}_{1} x + {b}_{1} y + dx \\ {y}^{′} = {a}_{2} x + {b}_{2} y + dy\end{matrix} \qquad ( 4 )$$

Also, the shift components dx and dy indicate the positional shift amount calculated from the electron beam eij and the wafer flatness ΔZ, and are represented by the following Formula (5):

$$\{ \begin{matrix}dx = dx\_ij \\ dy = dy\_ij\end{matrix} \qquad ( 5 )$$

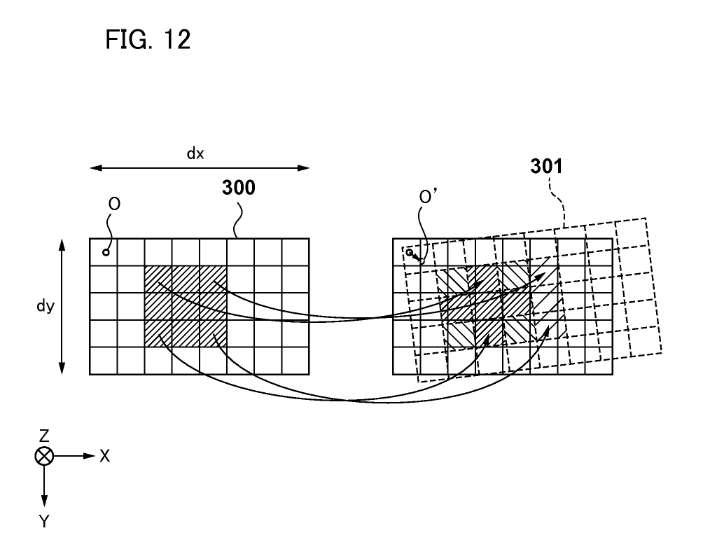

Next, the main controller C1 corrects drawing data with the relationship determined in step S202 (step S203). FIG. 11 is a schematic: diagram illustrating the positional relationship between the data P′ on the beam grid 301 and the original data grid 300 upon drawing data correction. For the sake of simplicity, all of 3×3 data of the beam grid 301 serve as data of full beam intensity. For example, the data P1 on the data grid 300 is drawn as the data P1′ on the beam grid 301 on the wafer 9. All the data P1′ fall within the drawing area of the original data grid 300, so that the drawing data is drawn at full beam intensify. On the other hand, as shown in FIG. 11, the data P2 on the data grid 300 is drawn as the data P2′ on the beam grid 301 on the wafer 9, and extends across the region in which the original drawing pattern is drawn and the region in which the original drawing pattern is not drawn. In this case, the main controller C1 calculates and corrects the drawing data from the ratio of the area of periphery data to the original data grid 300 within the region of the data P2′. For example, if the drawing area is 60% and the non-drawing area is 40%, the main controller C1 corrects the drawing data to 60% of full beam intensity. As a method for interpolating the drawing data from periphery data, linear interpolation of four surrounding pixels on the original data grid 300, which surround an arbitrary coordinates P′ (x′, y′) of the data P′ on the beam grid 301, may be performed. Alternatively, the drawing data may be corrected by bicubic interpolation with 16 surrounding pixels. FIG. 12 is a schematic diagram illustrating an example of the result of correcting the drawing data on the beam grid 301. The drawing data of the beam grid 301 is corrected from the drawing data of the data grid 300 while correcting the beam intensity of the electron beam e11.

Then, the main controller C1 determines whether or not the drawing data has been corrected for all electron beams (the electron beams e11 to enm) (step S204). Here, if the main controller C1 determines that the drawing data has not been corrected for all electron beams (NO in step S204), the process returns to step S201, and correction, is repeated. For example, the positional shift amount calculated from the degree of telecentricity and the wafer flatness for the electron beam e12 different from the electron beam e11 used in the aforementioned examples becomes (dx_12, dy_12), which is different from that of the electron beam e11. Thus, the main controller C1 also corrects the drawing data of the beam grid 301 for the electron beam e12 with the shift components dx_12 and dy_12 in the same manner. On the other hand, if the main controller C1 determines that the drawing data has been corrected for all electron beams (YES in step S204), drawing data correction processing ends.

Referring back to FIG. 4, next, the main controller C1 draws a pattern based on the corrected drawing data (step S107). Then, after drawing a desired pattern on the wafer 9, the main controller C1 carries the wafer 9 outside the drawing device 100 (step S108), and all the processing ends.

Although the flatness of the wafer 9 is measured for the entire surface of the wafer 9 at once in step S104, the present invention is not limited to this. For example, before drawing in a given shot, it is possible to measure the flatness of the shot, determine the drawing data in the shot, and perform drawing. Although global alignment is used in the alignment measurement in step S103, the present invention is not limited to this. For example, die-by-die alignment, in which alignment is performed before drawing in each shot, may also be performed.

As described above, the drawing device 100 corrects the shift components, and the rotation error and magnification error upon deflection, in consideration of the degree of telecentricity of the electron beam and the flatness of the wafer. In other words, the drawing device 100 can compensates distortion of the pattern to be drawn, resulting in an improvement in drawing precision.

Heretofore, a description has been given of the drawing device 100 alone. Hereinafter, a description will be given of a drawing apparatus according to the present embodiment including a plurality of drawing devices 100 serving as drawing stations. In each drawing device 100, a throughput or a processing capability for performing drawing on the wafer 9 is, for example, 10 wafers/hour (the number of wafers to be processed per one hour). Thus, a cluster system in which a plurality of drawing stations is used in combination as drawing apparatuses is constructed, resulting in an improvement in throughput. For example, when a cluster system in which ten drawing stations are combined is constructed, a user can use the cluster system as an entire drawing apparatus with a throughput of 100 wafers/hour. This is also advantageous in which the drawing apparatus can be readily used in combination with an exposure apparatus with the same throughput as that of the drawing apparatus.

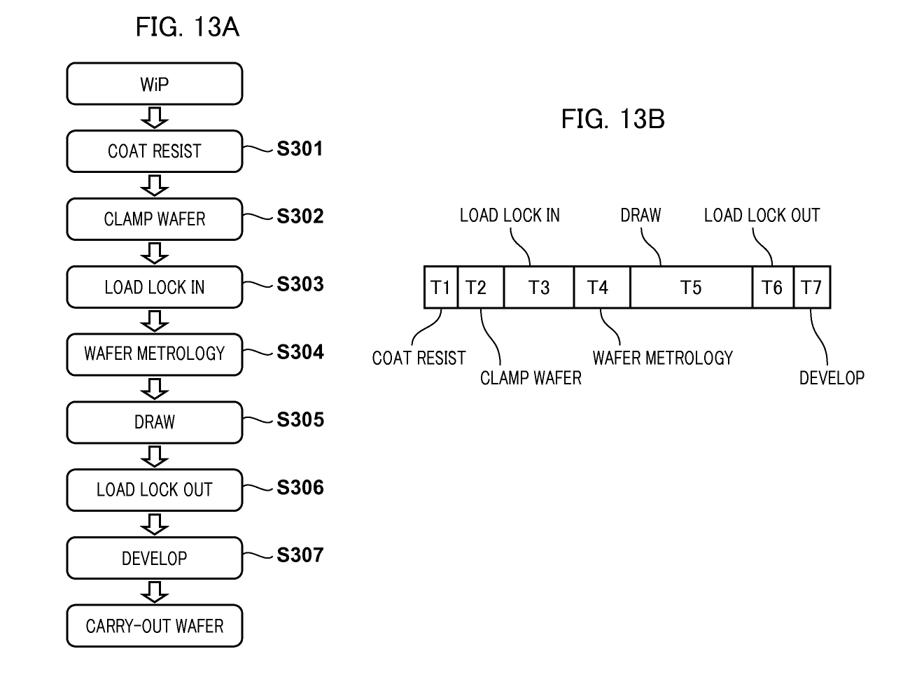

Firstly, a description will foe given of the steps of processing one wafer to be performed by the cluster system of the present embodiment. FIGS. 13A and 13B are diagrams illustrating the flowchart and the time chart of processing performed by a group (so-called “lithography cell”) of a coater/developer for coating a resist onto the wafer 9 and developing the coated wafer 9 and a drawing device. Firstly, a description will be given with reference to the flowchart shown in FIG. 13A. In this example, when processing for the wafer 9 starts (WiP: Wafer in Process), the processes in steps S301 to S306 are sequentially performed by the respective units (processing devices). The processes corresponding to the steps are resist, coating, wafer clamping, load lock in (from atmospheric pressure to vacuum), wafer metrology (focus, alignment measurement), drawing, load lock out (from vacuum to atmospheric pressure), and developing. On the other hand, FIG. 13B is a time chart illustrating the processing times taken by the units so as to approximately correspond to the actual elapsed times in association with FIG. 13A. As shown in FIG. 13B, the processing times to be taken by the units are T1 to 17, respectively.

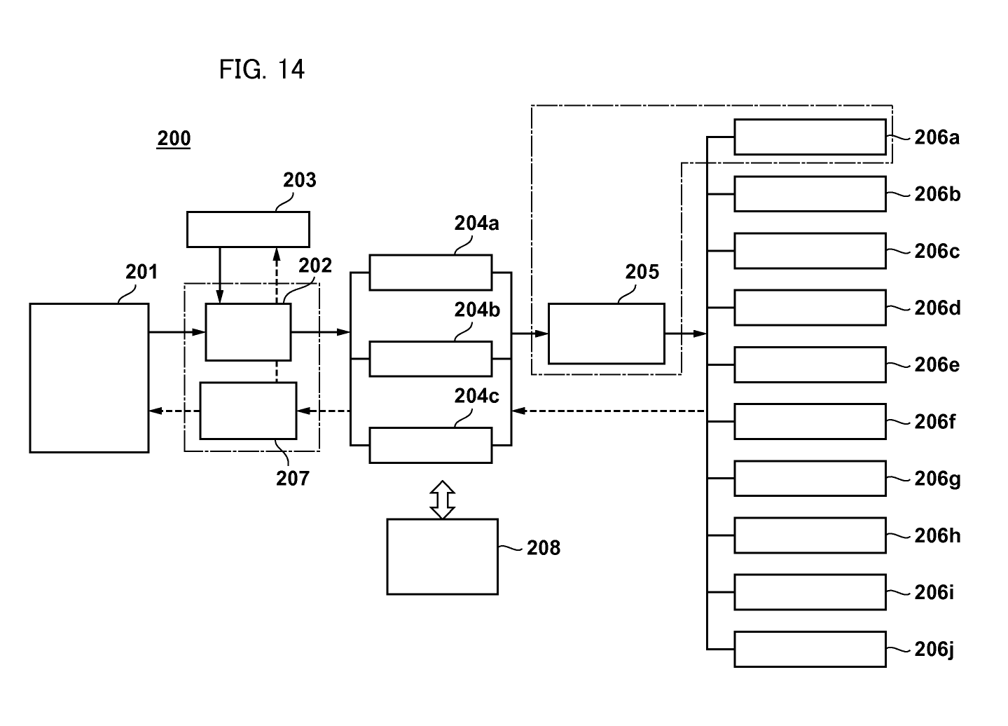

Next, a description will be given of a configuration of a drawing apparatus 200 according to the present embodiment and the processing operation performed thereby. FIG. 14 is a block diagram illustrating a configuration of the drawing apparatus 200 based on the assumption of the use of ten drawing stations. A coater/developer 201 coats a resist onto a plurality of wafers 9 transferred to the drawing apparatus 200 and then transfers the wafer 9 to be treated to a clamp station 202. The clamp station 202 aligns the wafer 9 received from the coater/developer 201 with the wafer chuck 15 supplied from a chuck station 203 and then holds (clamps) the aligned wafer 9. If drawing is performed on the wafer 9 under a vacuum environment in the absence of convective heat transfer, the thermal energy of the electron beam accumulates in the wafer 9. Thus, in the clamp station 202, a heat transfer path for the wafer 9 is provided, so that the wafer 9 and the wafer chuck 15 are connected to each other with a low heat resistance. An example for connecting the wafer 9 to the wafer chuck 15 with a low heat resistance includes a mechanism for encapsulating gas or liquid serving as a low heat resistant medium between the wafer 9 and the wafer chuck 15. Note that the mechanism for feeding/collecting gas or liquid is required for the clamp processing. If such mechanisms are implemented in the drawing stations 206, the structure of the drawing stations 206 will be complicated. Thus, in order to avoid complication of the structure of the drawing stations 206, it is preferable that clamp processing is performed by the clamp station 202 provided upstream as described above. A load lock chamber 204 (204a to 204c) receives the wafer chuck 15 on which the wafer 9 is held and performs evacuation therein. At this time, the load lock chamber 204 decreases its internal pressure from an atmospheric pressure or an environmental pressure in the clamp station 202 to a pressure that allows wafer transfer to/from the metrology station. 205 under high vacuum. For a pressure that allows wafer transfer, the lower limit value of a differential pressure between chambers, at which the raise of particles, the inflow of moisture in the load lock chamber environment, or the like is permitted upon opening of a gate valve (not shown) provided between the load lock chamber 204 and the metrology station 205, is applied. While, in FIG. 14, the number of the load lock chambers 204 installed is three, the method for determining the number of the load lock chambers 204 installed will be described below. The metrology station (measuring device) 205 receives the wafer chuck 15 on which the wafer 9 is held from the load lock chamber 204, and then performs measurement processing of alignment between the wafer 9 and the wafer chuck 15 and shape measurement processing such as the aforementioned wafer flatness or the like. As described above, the drawing stations 206 (206a to 206j) correspond to the drawing devices 100, respectively. Each of the drawing stations 206 loads the wafer chuck 15 on which the wafer 9 is held on the wafer stage 13 and then aligns the wafer 9 with the reference position of the electron beam to thereby perform drawing. The wafer 9 for which drawing processing has been completed by any one of the drawing stations 206 returns to any one of the load lock chambers 204 in a vacuum state as shown by the broken line in FIG. 14. At this time, the pressure in the load lock chamber 204 to which the wafer 9 has been transferred is increased from an atmospheric pressure or an environmental pressure in the clamp station 202 to a pressure that allows wafer transfer. Here, a pressure that allows wafer transfer is also the one that satisfies the same differential pressure condition as described above. The unclamp station 207 removes the hold state between the transferred wafer 9 and the wafer chuck 15. In this example, the removal of the hold state is to remove gas or liquid serving as a low heat resistant medium. Then, the processed wafer 9 is transferred to the coater/developer 201 for development, whereas the wafer chuck 15 is transferred to (accommodated in) the chuck station 203, so that drawing processing for one wafer 9 ends. The plurality of units (elements) constituting the drawing apparatus 200 is integrally controlled by the system controller (first controller) 208.

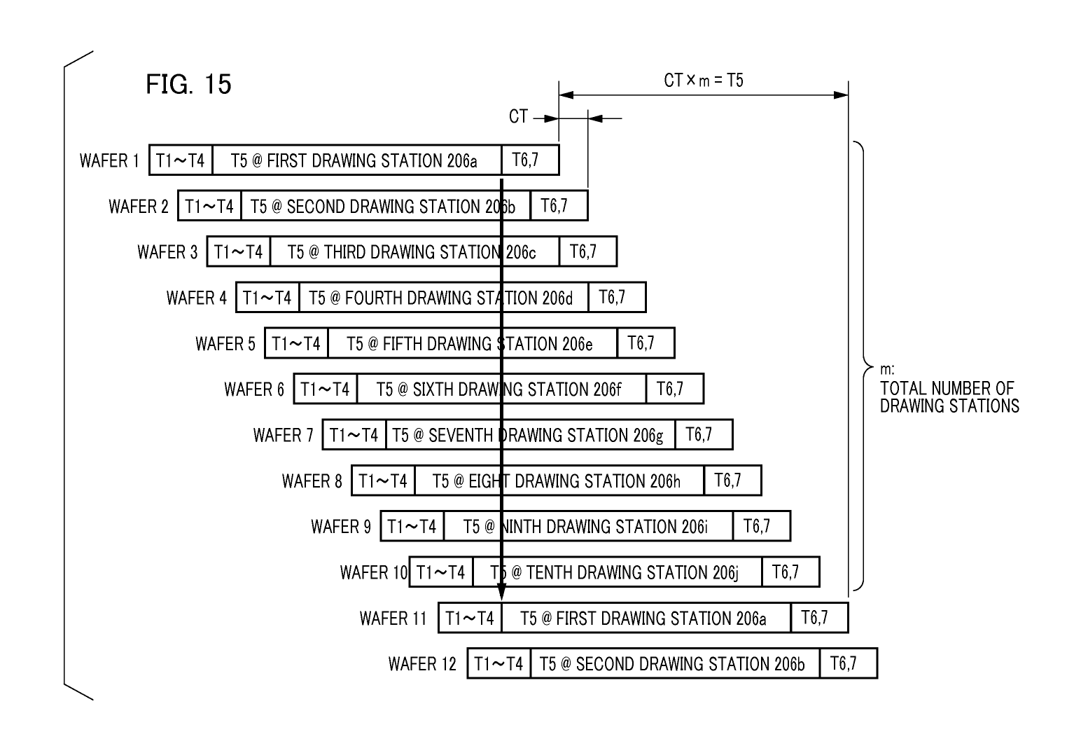

Next, a description will be given of a time chart of the drawing apparatus 200 and a cycle time CT which means a time interval required for the drawing stations 206 to complete processing for one wafer in sequence. FIG. 15 is a time chart of the drawing apparatus 200. As shown in FIG. 15, in the drawing apparatus 200, the wafers 9 are processed one-by-one in parallel at a constant time interval (the cycle time CT). It is also contemplated that processing for the wafer 9 is not performed at a constant time. In such a case, the operation in the drawing apparatus 200 is not uniform, resulting in non-uniform state of heat and vibration. This leads to a factor of occurrence of errors for maintaining an apparatus performance at a constant level. Thus, it should be preferable that the drawing apparatus 200 employs a system in which the wafers 9 are processed at a constant time interval, i.e., the cycle time CT. As described above, assume that each of the drawing stations 206 has a throughput of 10 wafers/hour and the entire drawing apparatus 200 has a throughput of 100 wafers/hour. In this case, in one drawing station 206, when simply divided for each wafer in spite of the presence of various time factors upon actual processing, a time (the processing time T5) required for processing one wafer 9 is 6 minutes. In contrast, in the entire drawing apparatus 200, a time required for processing one wafer 9 is 36 seconds which is the cycle time CT shown in FIG. 15.

In the drawing apparatus 200, a unit that requires the longest processing time is each of the drawing stations 206, so that the drawing stations 206 need to be operated at all times in order to achieve a desired throughput. In other words, upon completion of drawing processing during the processing time T5, one drawing station 206 needs to perform drawing processing by immediately receiving the next wafer 9. As an example illustrating the use of this feature, in FIG. 15, an arrow is drawn from the time point of the completion of drawing processing by the first drawing station 206a which firstly starts drawing processing to the time point of the start of next drawing processing by the first drawing station 206a. The drawing apparatus 200 needs to be operated according to a time chart such that no time lag occurs between two time points indicated by the arrow. Specifically, the throughput of the entire drawing apparatus 200 is constrained (rate-limited) by the processing time T5 taken by the drawing stations 206 and the number (total number) m of drawing stations 206 in the plurality of drawing stations 206. In other words, the throughput of the entire drawing apparatus 200 is not constrained by the processing time taken by the wafer transfer system as an advantage of clustering. In this example, as can be seen with reference to FIG. 15, the cycle time CT is specifically the processing time T5 taken by the drawing stations 206 divided by the number m of drawing stations 206 in the plurality of drawing stations 206. Thus, in order to maximize the effect of clustering in the drawing apparatus 200, the processing time taken by units other than the drawing stations 206 needs to be set shorter than the cycle time CT.

Here, by considering the aforementioned flatness measurement of the wafer 9, it is preferable that a measurement time is shorter than the cycle time CT (no greater than constant time interval) but is close to the cycle time CT from the viewpoints of maintaining the state of heat and vibration and the apparatus performance at a constant level. The reason for this is that measurement can be performed at a fine pitch with an increase in measurement time as long as possible and the averaging effect can be obtained with an increase in the number of measurement times, resulting in an improvement in measurement precision. As described above, the processes to be performed in a time period which is shorter than the cycle time CT but is close to the cycle time CT including the carry in/out time and the set time of the wafer 9 are advantageous for flatness measurement, and the same applied to other units.

However, in order to exhibit the performance of the entire drawing apparatus 200, some of the processing times taken by the units other than the drawing stations 206 exceeds the cycle time CT. Examples of the processing time exceeding the cycle time CT include the processing time T3 taken for “load lock in” processing or “load lock out” processing. The wafer carry-in processing time T3 taken by the load lock chamber 204 includes a time required for carrying in a wafer from the clamp station 202, an evacuation time, and a time required for carrying out a wafer to the metrology station 205. Likewise, the wafer carry-out processing time T6 taken by the load lock chamber 204 includes a time required for carrying in a wafer from the drawing station 206, an atmosphere release time, and a time required for carrying out a wafer to the unclamp station 207. In particular, since a long evacuation time is taken because a high vacuum environment is required for the drawing station 206, a standard processing time (including evacuation, atmosphere release, and wafer transfer) T3 taken by the load lock chamber 204 is assumed to be about 100 seconds. In other words, the processing time T3 is longer than the cycle time CT (36 seconds). Thus, in order to deal with this, a plurality of load lock chambers 204 needs to be provided in the drawing apparatus 200 so as to satisfy the aforementioned conditions.

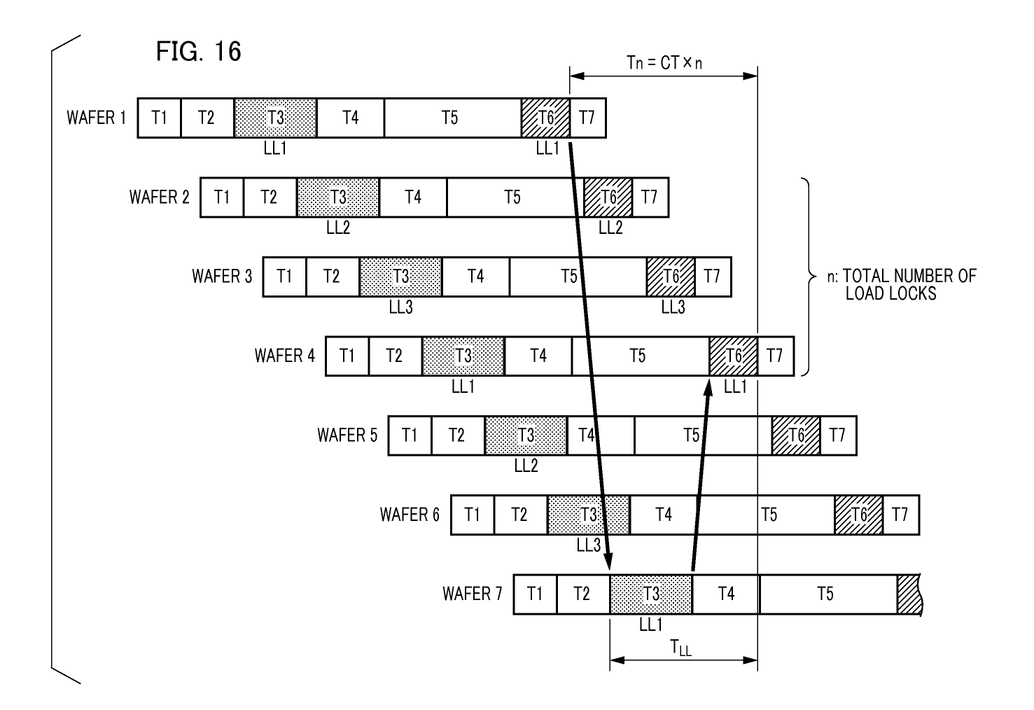

FIG. 16 is a diagram illustrating a time chart of the drawing apparatus 200 based on the assumption that the drawing apparatus 200 includes a plurality of load lock chambers 204. FIG. 16 illustrates the number of load lock chambers 204, which does not constrain wafer transfer rate, for performing processing to be handled by the load lock chambers 204. Firstly, it is assumed that the drawing apparatus 200 is in a steady state where the drawing apparatus 200 performs continuous processing for the wafers 9. At this time, assume that, for example, the processing (the processing time T6) for carrying out the first wafer (Wafer 1) is completed in the first load lock chamber 204a (LL1). Then, if the processing in the first, load lock chamber 204a can be shifted to the processing for carrying in the next wafer (processing for carrying in the seventh wafer (Wafer 7) (the processing time T3)) without interrupting other processing, the throughput of the drawing apparatus 200 is not constrained by the processing performed by the load lock chambers 204. Here, a time Tn from the completion of carry-out processing for the first wafer to the completion of carry-out processing for the fourth wafer (Wafer 4) in the first load lock chamber 204a is represented by the product (Tn=CT×n) of the cycle time CT and the number n of load lock chambers 204 in the plurality of load lock chambers 204. Also, the first load lock chamber 204a needs to have a vacuum environment therein in order to start carry-out processing for the fourth wafer. If an evacuation can be performed during carry-in processing for the seventh wafer, it can be said that the drawing apparatus 200 is in a steady state. Thus, the processing time T_{LL} taken by the load lock chambers 204 is represented by the summation (T_{LL}=T3+T6) of the processing time T3 taken for wafer carry-in processing and the processing time T6 taken for wafer carry-but processing. In other words, in order to prevent the fact that the throughput of the entire drawing apparatus 200 is constrained by the processing time taken by the load lock chamber 204 in a steady state, the relationship of T_{LL}<Tn needs to be satisfied. Consequently, the optimum number n of load lock chambers 204 in the plurality of load lock chambers 204 in terms of throughput is defined as the number not less than an integer rounding up n where n satisfies the relationship of n>(T3+T6)/CT. In the present embodiment, the number of load lock chambers 204 in the plurality of load lock chambers 204 is three as an example, but the number of load lock chambers 204 in the plurality of load lock chambers 204 may be determined as appropriate in accordance with the definition.

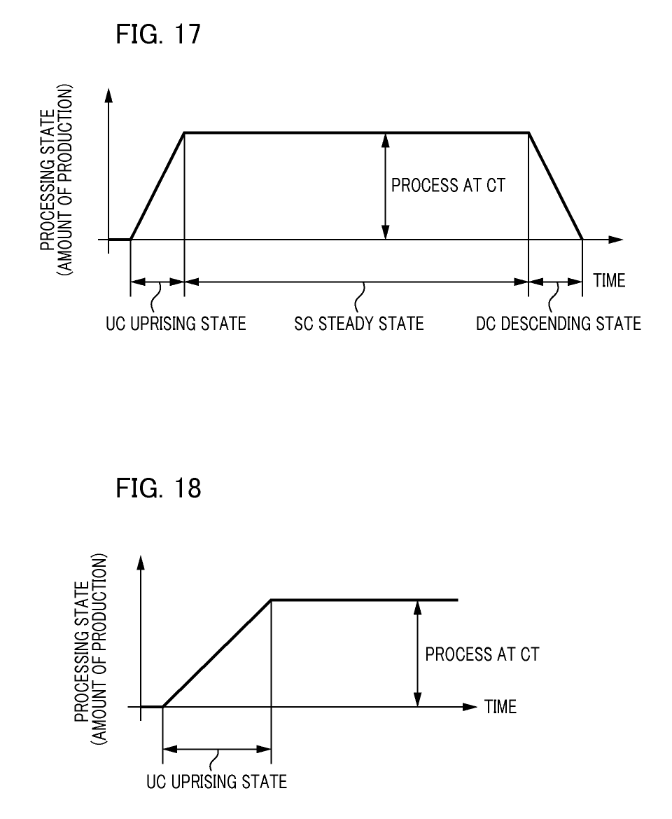

Here, referring to FIG. 15, processing for the first wafer is completed at a time point of completion of development (the processing time T7) for the first wafer subjected to drawing processing in the first drawing station 206a, and processing for the subsequent wafers 9 is completed in sequence at the intervals of the cycle time CT. In other words, there is no wafer 9 for which all the processing has been completed in the drawing apparatus 200 until development has been completed for the first wafer. FIG. 17 is a graph conceptually illustrating the amount of production per unit time with respect to a time taken by the drawing apparatus 200. The amount of production gradually increases at a time point of completion of development for the first wafer subjected to drawing processing in the first, drawing station 206a (uprising state UC). Next, when processing is being performed in all of the drawing stations 206, the amount of production becomes constant (steady state SC). Finally, when the remaining number of wafers 9 to be treated is small, the amount of production gradually decreases (descending state DC) and processing is completed at a time point at which there is finally no wafer 9 to be treated. Here, since a cluster system is employed in the drawing apparatus 200 of the present embodiment for mass production, it is contemplated that the time in the steady state SC is long. Thus, in the drawing apparatus 200, if is contemplated that the low amount of production in both the uprising state UC and the descending state DC can be ignored but processing for the wafers 9 advances at intervals of the cycle time CT when the drawing apparatus 200 is in the steady state SC.

FIG. 18 is a graph conceptually illustrating the amount of production per unit, time with respect to a time taken by the drawing apparatus 200 when the number of units installed in the drawing apparatus 200 is large, where FIG. 18 is a graph corresponding to that shown in FIG. 17 as a reference. As described above, if the drawing apparatus 200 is constructed as a system in which processing is performed by various units, the uprising state UC is elongated accordingly, resulting in a difficulty in shifting to the steady state SC. Thus, when the drawing apparatus 200 is constructed, the number of units installed therein needs to be set such that the low amount of production in both the uprising state UC and the descending state DC can be ignored.

As described above, if the drawing apparatus 200 is provided with a plurality of units which require the longest time for processing and employs a time chart such that the units are operated at all times, a desired cycle time CT (including productivity and throughput) can be realized. On the other hand, the processing times (in this example, processing times T1 to T4, T6, and T7) taken by units other than the unit which requires the longest time for processing needs to be set in advance so as not to be longer than the cycle time CT. In particular, in the present embodiment, the flatness of the wafer needs to be measured with accuracy as high as possible in order to reduce a drawing positional shift of the electron beam due to the product of the degree of telecentricity and the wafer flatness. Thus, the metrology station 205 may also perform the measurement operation for measuring the flatness of the wafer for a period of time which is shorter than the cycle time CT but is close to the cycle time CT. As in the definition for determining the number of load lock chambers 204 in the plurality of load lock chambers 204, the number of metrology stations 205 in the plurality of metrology stations 205 to be installed may also be determined in accordance with the definition. Here, assume that the measurement precision of the wafer flatness in the metrology station. 205 is strictly set (higher priority is given to the measurement precision). In this case, firstly, even if the measurement precision is strictly set but the measurement time to be taken by one metrology station 205 is not longer than the cycle time CT, only one metrology station 205 needs to be installed in the drawing apparatus 200. Furthermore, in this case, the metrology station 205 may be provided in a unit separate from the drawing station 206 as described above but may also be provided as a part of one drawing station 206 as shown by the area enclosed by a chain-dotted line shown in, for example, FIG. 14. On the other hand, if the measurement time to be taken by one metrology station 205 is longer than the cycle time CT due to strict setting of the measurement precision, a plurality of metrology stations 205 may be installed in the drawing apparatus 200. In contrast to the case where higher priority is given to the measurement precision, it is also contemplated that the throughput of the entire drawing apparatus 200 is strictly kept to a desired level, that is, higher priority is given to the throughput. For example, there are cases where the measurement time to be taken by one metrology station 205 is longer than the cycle time CT upon measuring the flatness of the wafer with a given measurement precision. In order to deal with this, for example, the system controller 208 suppresses the measurement precision within an allowable range instead of increasing the number of metrology stations 205 in the plurality of metrology stations 205 to be installed, so that the measurement time may be not longer than the cycle time CT. In this manner, a desired throughput can be readily realized without changing the number of metrology stations 205 in the plurality of metrology stations 205 to be installed. Thus, even if the drawing apparatus 200 is employed by an inexpensive process which requires high throughput but uses loose standards for both the telecentric characteristics of each electron beam or the flatness of the wafer 9, the drawing apparatus 200 can attain a high overlay precision. This makes it possible to provide the drawing apparatus 200 with a high CoO (Cost of Ownership), which is also greatly advantageous for a user.

As described above, according to the present embodiment, a drawing apparatus that is advantageous in terms of, for example, overlay precision and throughput may be provided.

### (Article Manufacturing Method)

An article manufacturing method according to an embodiment of the present invention is preferred in manufacturing an article such as a micro device such as a semiconductor device or the like, an element or the like having a microstructure, or the like. The manufacturing method may include a step of forming a latent image pattern on a photosensitive agent applied on a substrate using the above-mentioned drawing apparatus (a step of performing drawing on a substrate), and a step of developing the substrate formed the latent image pattern thereon in the forming step. Furthermore, the article manufacturing method may include other known steps (oxidizing, film forming, vapor depositing, doping, flattening, etching, resist peeling, dicing, bonding, packaging, and the like). The device manufacturing method of this embodiment has an advantage, as compared with a conventional device manufacturing method, in at least one of performance, quality, productivity and production cost of a device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-277472 filed on Dec. 19, 2012, which is hereby incorporated by reference herein in its entirety.

What is claimed is:

1. A drawing apparatus including a plurality of drawing devices each of which is configured to draw a pattern on a substrate with a plurality of charged particle beams, the plurality of drawing devices performing respective drawings in parallel, the drawing apparatus comprising:
a measuring device configured to measure a flatness of the substrate,
wherein each of the plurality of drawing devices comprises:
a charged particle optical system configured to irradiate the substrate with the plurality of charged particle beams; and
a controller configured to control an operation of the charged particle optical system so as to compensate for distortion of the pattern which is determined by data of inclination of a charged particle beam of the charged particle beams with respect to an axis of the charged particle optical system and data of the flatness measured by the measuring device.

2. The drawing apparatus according to claim 1, wherein a processing time taken by the measuring device for a substrate is not longer than a time interval at which the plurality of drawing devices complete respective processings for the respective substrates in sequence.

3. The drawing apparatus according to claim 2, wherein the time interval is a time interval obtained by dividing a processing time taken by one of the plurality of drawing devices by the number of drawing devices in the plurality of drawing devices.

4. The drawing apparatus according to claim 1, wherein the apparatus comprises a plurality of the measuring device.

5. The drawing apparatus according to claim 4, wherein a time interval at which the plurality of the measuring device complete respective processings for the respective substrates in sequence is not longer than a time interval at which the plurality of drawing devices complete respective processings for the respective substrates in sequence.

6. A drawing apparatus including a plurality of drawing devices each of which is configured to draw a pattern on a substrate with a plurality of charged particle beams, the plurality of drawing devices performing respective drawings in parallel, the drawing apparatus comprising:
a measuring device configured to measure a flatness of the substrate; and
a first controller configured to control the measuring device,
wherein each of the plurality of drawing devices comprises:
a charged particle optical system configured to irradiate the substrate with the plurality of charged particle beams; and
a second controller configured to control an operation of the charged particle optical system so as to compensate for distortion of the pattern which is determined by data of inclination of a charged particle beam of the charged particle beams with respect to an axis of the charged particle optical system and data of the flatness measured by the measuring device,
wherein the first controller is configured to control an operation of the measuring device such that a processing time taken by the measuring device for a substrate is not. longer than a time interval at which the plurality of drawing devices complete respective processings for the respective substrates in sequence.

7. A method of manufacturing an article, the method comprising steps of:
drawing a pattern on a substrate using a drawing apparatus; and
developing the substrate on which the pattern has been drawn,
wherein the drawing apparatus includes a plurality of drawing devices each of which is configured to draw a pattern on a substrate with a plurality of charged particle beams, the plurality of drawing devices performing respective drawings in parallel, the drawing apparatus including:
a measuring device configured to measure a flatness of the substrate,
wherein each of the plurality of drawing devices includes:
a charged particle optical system configured to irradiate the substrate with the plurality of charged particle beams; and
a controller configured to control an operation of the charged particle optical system so as to compensate for distortion of the pattern which is determined by data of inclination of a charged particle beam of the charged particle beams with respect to an axis of the charged particle optical system and data of the flatness measured by the measuring device.
